(19) United States
(12) Patent Application Publication
(10) Pub. No.: US 2012/0052615 A1
(43) Pub. Date: Mar. 1, 2012

(54) METHOD AND STRUCTURE FOR REDUCING DARK CURRENT IN A CMOS IMAGE SENSOR

(75) Inventors: Jieguang Huo, Shanghai (CN); Jianping Yang, Shanghai (CN)

(73) Assignee: Semiconductor Manufacturing International (Shanghai) Corporation, Shanghai (CN)

(21) Appl. No.: 13/011,819

(22) Filed: Jan. 21, 2011

(30) Foreign Application Priority Data
Jan. 22, 2010 (CN) 201010100031.6

(51) Int. Cl. H01L 31/18

(52) U.S. Cl. 438/73; 257/E31.091

(57) ABSTRACT

A method of forming a CMOS image sensor device includes providing a semiconductor substrate having a P-type impurity characteristic. The semiconductor substrate includes a surface region. The method forms a gate oxide overlying the surface region and forms an N type region in a portion of the semiconductor substrate. The method forms a photodiode device region from at least the N-type region. The method forms a first gate structure and multiple second gate structures overlying the gate oxide layer. The method forms a blanket spacer layer overlying the first gate structure and the second gate structures. A protective layer is formed overlying the photodiode device region and a portion of the third gate structure. The method forms one or more spacer structures using the blanket spacer structure while maintaining the protective layer overlying at least the photodiode region.

### CROSS-REFERENCES TO RELATED APPLICATIONS

This application claims priority to Chinese Application No. 201010100031.6, filed Jan. 22, 2010, which is commonly owned and incorporated by reference herein for all purposes.

### BACKGROUND OF THE INVENTION

Embodiments of the present invention are directed to integrated circuits and their processing for the manufacture of semiconductor devices. More particularly, embodiments of the invention provide a method and a structure for manufacturing a CMOS image sensor device having a reduced dark current characteristics for advanced application. But it would be recognized that embodiments of the invention have much broader ranges of applicability.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry,” has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is, a given process typically only works down to a certain feature size, and then either the process or the device layout needs to be changed.

An example of such a limit can be found in image sensors. As demand for pixel sensitivity and pixel density increases in consumer applications, pixel layout and related integrated circuit design and processing become more critical. These and other limitations will be described in further detail throughout the present specification and more particularly below.

From the above, it is seen that an improved technique for processing semiconductor image sensor devices is desired.

### BRIEF SUMMARY OF THE INVENTION

Embodiments of the present invention provide a method and a structure of forming a CMOS image sensor device. More particularly, embodiments of the invention provides a method and structure for manufacturing a CMOS image sensor device having reduced process steps and the resulting CMOS image sensor having a reduced dark current. But it would be recognized that embodiments of the invention have much broader ranges of applicability. For example, the method can be applied to manufacturing other integrated circuits such as logic devices, memory devices, and others.

A specific embodiment provides a method for forming a CMOS image sensor device. The method includes providing a semiconductor substrate having a P-type impurity characteristic including a surface region, and forming a gate oxide overlying the surface region. The method also includes forming one or more first gate structures overlying a first portion of the gate oxide layer, one or more second gate structure overlying a second portion of the gate oxide layer, and a third gate structure overlying a third portion of the gate oxide layer. An N-type impurity region is formed in a portion of the semiconductor substrate to form a photodiode device region from at least the N-type impurity region. In an embodiment, the N-type impurity region is adjacent to the third gate structure. A blanket spacer layer is formed overlying the one or more first gate structures, the one or more second gate structures, and the third gate structure. The method also includes forming a protective layer overlying the photodiode device region and a first portion of the third gate structure. The method further includes forming one or more spacer structures using the blanket spacer layer for the one or more first gate structures, the one or more second gate structures, and exposed portion of the third gate structure while maintaining the protective layer overlying the photo diode device region and the first portion of the third gate structure. The method additionally includes removing the protective layer.

In another embodiment, a method of forming a CMOS image sensor device includes forming a first well region having a first impurity type, forming a second well region having a second impurity type, and forming a photodiode device region adjacent to the second well region. The method also includes forming one or more first gate structures overlying a first portion of the first well region, forming one or more second gate structures overlying a second portion of the second well region, forming a third gate structure between the photodiode device region and the second well region. Then an insulating layer is formed over the first well region, the second well region, the photodiode device region, and the third gate structure. The method further includes removing a first portion of the insulating layer over the first well region, a second portion of the insulating layer over the second well region, and a third portion of the insulating layer over the third gate structure. The method also includes forming one or more spacers in the first well region, one or more spacers in the second well region, and one spacer adjacent to one side of the third gate structure. The method further includes maintaining a fourth portion of the insulating layer over the photodiode device region and over a portion of the third gate structure adjacent to the photodiode device region.

In an embodiment of the method described above, the method also includes, after the spacer formation step, using a first mask for implanting impurities of the second type into the first well region. In another embodiment, the method also includes after the spacer formation step, using a second mask for implanting impurities of the first type into the second well region.

Embodiments of the present invention provide many benefits over conventional techniques. For example, embodiments of the present invention provides an easy to use process that relies upon conventional technology. In some embodiments, the method provides higher device reliability and performance. Depending upon the embodiment, one or more of these benefits may be achieved. These and other benefits will be described in more throughout the present specification and more particularly below.

Various additional embodiments, features, and advantages of the present invention can be more fully appreciated with reference to the detailed description and accompanying drawings that follow.

### BRIEF DESCRIPTION OF THE DRAWINGS

FIG. 1 is a diagram illustrating fabrication of a CMOS image sensor according to a convention method;

FIG. 2 is a simplified process flow illustrating a method of fabricating a CMOS image sensor according to an embodiment of the present invention;

FIG. 3-6 are simplified diagrams illustrating a part of a method of fabricating a CMOS image sensor according to an embodiment of the present invention; and

FIG. 7 is a simplified diagram illustrating a plot of an experiment result according to an embodiment of the present invention.

### DETAILED DESCRIPTION OF THE INVENTION

Embodiments of the present invention provide a method of forming a CMOS image sensor device. More particularly, the embodiments described herein provide a method and structure for manufacturing a CMOS image sensor device having a reduced dark current. But it would be recognized that the invention has a much broader range of applicability. For example, the method can be applied to manufacturing other integrated circuits such as logic devices, memory devices, and others.

The CMOS image sensor device is emerging as the preferred device technology for digital consumer applications. To enable improved pixel sensing performance, CMOS image sensor technology requires improved pixel layout design and integrated circuit processing, among others. Dark current is a major factor influencing sensor performance especially under a low light condition. Factors that may contribute to dark current include defects on the silicon surface and silicon-gate oxide interface in photodiode regions and surrounding regions. Such limitations and others will be described in more detail throughout the specification and particularly below.

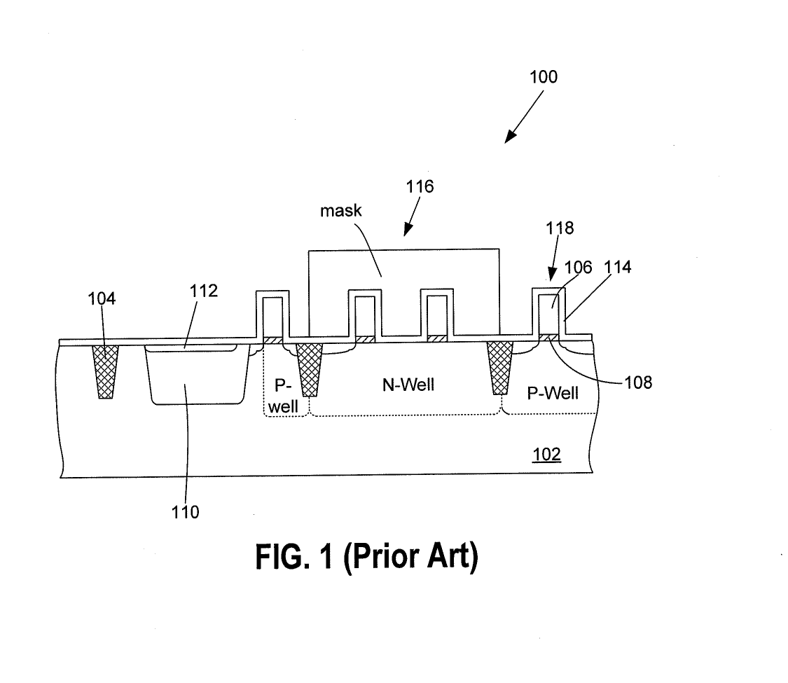

FIG. 1 is a simplified diagram illustrating a fabrication of a CMOS image sensor 100 according to a conventional method. As shown, the conventional method includes providing a semiconductor substrate 102. The semiconductor substrate can be a silicon wafer doped with, for example, a P type impurity. The conventional method also includes providing isolation regions 104 in portions of the semiconductor substrate. As shown in FIG. 1, at least one gate structure 106 is formed overlying a gate dielectric 108 overlying the semiconductor substrate. The gate dielectric is usually formed using a grown thermal oxide. The conventional method also includes forming a photosensitive region 110 in a portion of the semiconductor substrate. The photosensitive region is formed using an N type impurity region and P type impurities. A P type impurity region 112 is also provided in a surface region of the photosensitive region to form a pinned photodiode structure. The pinned photodiode reduces certain dark current in the conventional CMOS image sensor device. The conventional method forms spacer structures overlying each of the gate structures.

In sensor 100, the spacer structures are formed using more than one etching processes. For example, the conventional method performs a first spacer etch to form spacer structures 114 overlying the gate structures for P channel device 118 while the N channel devices region 116 is being masked as shown in FIG. 1. The conventional method then masks the P channel device region and performs a second spacer etch process to form spacer structures overlying the gate structures for N channel devices 118. The multiple spacer etch processes can cause misalignment resulting in overdevelopment or overlapping of the N channel and P channel device regions. The etching processes also cause defects in the surface region (including the gate dielectric surface and gate dielectric/Si interface) as well as surrounding region of the photodiode device region. Such defects cause leakage current especially in low light condition. These and other limitation of the conventional method for fabricating CMOS image sensor device will be described in more detail below.

In order to remedy the limitations in conventional technology, embodiments of the present invention provide improved methods for CMOS image sensors, some of which are described below.

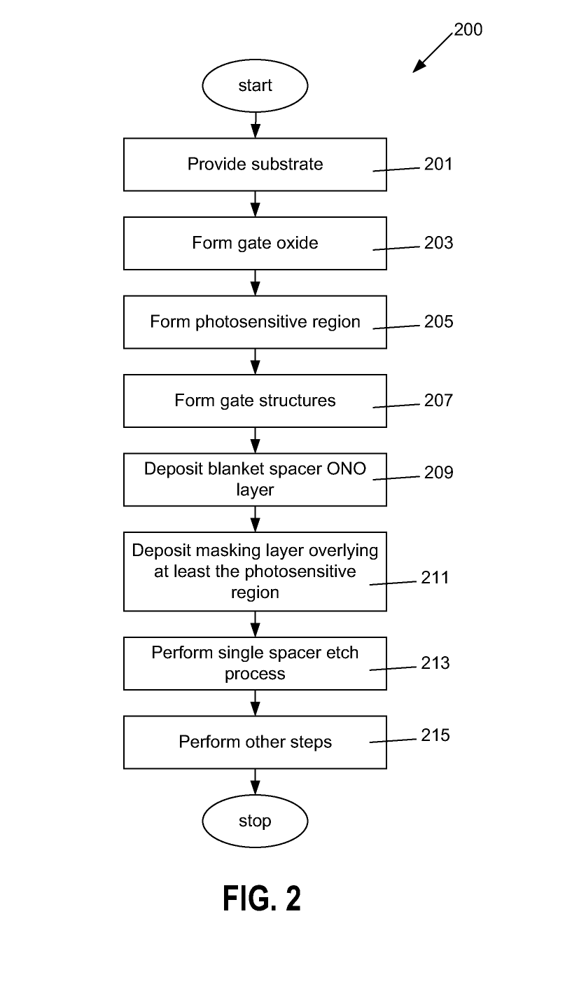

FIG. 2 is a simplified process flow diagram illustrating a method of fabricating a CMOS image sensor according to an embodiment of the present invention. The diagram is merely an example and should not unduly limit the scope of the claims herein. One skilled in the art would recognize other variations, modifications, and alternatives. As shown, the method provides a semiconductor substrate doped with a P type impurity (Step 201). The semiconductor substrate can be a silicon wafer, a silicon on insulator substrate, a silicon germanium substrate and the like. The method forms a gate dielectric layer overlying a surface region of the semiconductor substrate (Step 203). The gate dielectric layer can be a grown thermal oxide in a specific embodiment. The method forms a N type impurity region within the semiconductor substrate to form a photosensitive region in a portion of the semiconductor substrate (Step 205). The photosensitive region is formed using at least the N type impurity region and P type impurities in a specific embodiment. The method forms a plurality of first gate structures, a plurality of second gate structures, and a third gate structure overlying a surface region of the semiconductor substrate (Step 207). The method includes forming a blanket dielectric layer overlying at least the first gate structure and the plurality of second gate structures (Step 209). The blanket dielectric layer may have an ONO structure in a preferred embodiment. The method includes forming a masking layer overlying the photosensitive region (Step 211) and its surrounding regions, for example, a diffusion region for the photosensitive region. The method performs a spacer etch process to form spacer structures overlying each of the plurality of first gate structures, each of the plurality of second gate structures and a portion of the third gate structure, while the patterned photosensitive region protects the photosensitive region (Step 213). The method continues with other process steps to complete the CMOS image sensor device (Step 215). Of course there can be other variations, modifications, and alternatives.

The above sequence of steps provide a method of forming a CMOS image sensor device according to an embodiment of the present invention. As shown, the method uses a combination of steps including a way of forming CMOS image sensor devices having an improved spacer forming method to achieve a low junction leakage current, for example, less than about 0.5 fA/pixel in a specific embodiment. Other alternatives can also be provided where one ore more steps are added, one or more steps are removed, or one or more steps may be provided in a different sequence without departing from the scope of the claims herein. One skilled in the art would recognize other variations, modifications, and alternatives.

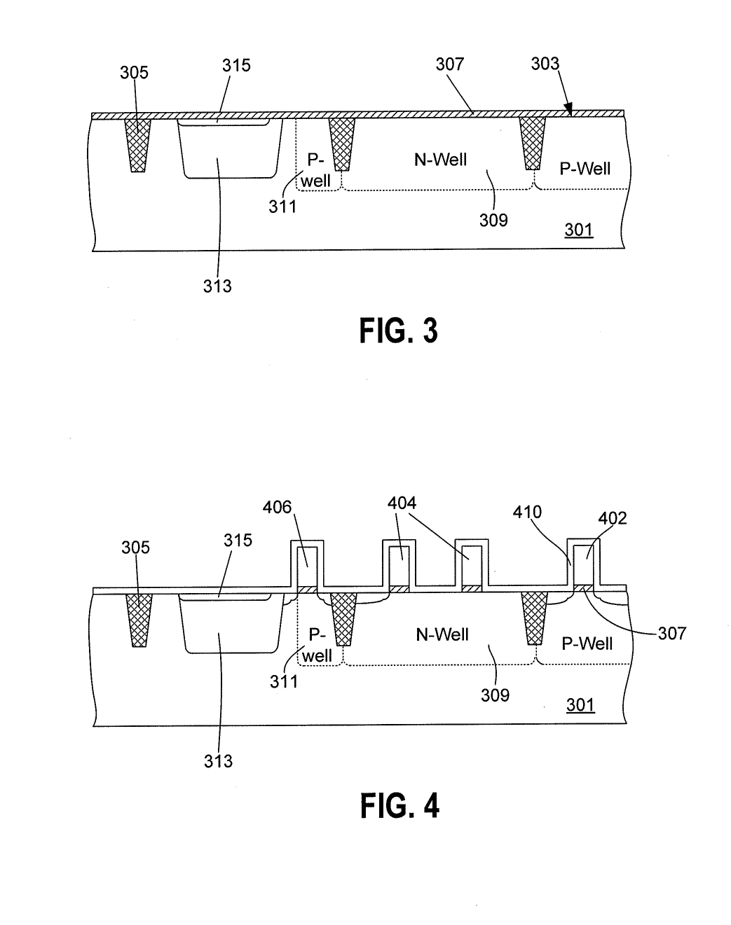

FIG. 3-7 are simplified diagrams illustrating a method of fabricating a CMOS image sensor device according to embodiments of the present invention. These diagrams are merely example and should not unduly limit the scope herein. One skilled in the art would recognize other variations, modifications, and alternatives. As shown in FIG. 3, a semiconductor substrate 301 having a surface region 303 is provided. The semiconductor substrate can be a silicon substrate, a silicon on insulator (SOI), silicon germanium and the like. In a specific embodiment, the semiconductor substrate is a silicon wafer characterized by a P-type impurity. Of course, an N-type silicon may also be used, depending on the embodiment. The method forms a plurality of isolation regions 305 in portions of the semiconductor substrate. In a specific embodiment, the isolation regions can be provided using shallow trench isolation commonly known as STI. Other isolation techniques such as field oxide may also be used depending on the application. Shallow trench isolation may be formed using steps including patterning, etch and a dielectric (for example high density plasma, commonly known as HDP oxide) fill. Other isolation structures such as field oxides may also be used depending on the application.

The method includes forming a gate dielectric layer 307 overlying the surface region. The gate dielectric layer may be provided using a high quality grown thermal oxide having a thickness ranging from about 20 Angstroms to about 200 Angstroms. Other gate dielectric materials may also be used. These other gate dielectric materials may include silicon nitride, silicon oxynitride or an ONO stack (oxide on nitride on oxide) or high K materials depending on the application. As shown, N well region 309 and P well regions 311 are formed in portions of the semiconductor substrate. Of course there can be other variations, modifications, and alternatives.

Referring still to FIG. 3, the method includes forming a photodiode device region or a photosensitive region 313 in a portion of the semiconductor substrate. The photosensitive region can be formed using an impurity opposite in polarity to the impurity of semiconductor substrate. For example, the photosensitive device region maybe formed by using an N type impurity for the P type substrate. Examples of such N type impurity include arsenic, phosphorus, antimony, and the like. In a specific embodiment, the photosensitive device region may use a pinned photodiode structure to reduce surface dark leakage current. The pinned photodiode structure includes a P type impurity region 315 in a surface region of the photosensitive region. Of course there can be other variations, modifications, and alternatives.

In FIG. 4, the method of forming a CMOS image sensor device according to embodiments of the present invention includes forming a plurality of gate structures overlying the gate dielectric layer. The plurality of gate structures include one or more first gate structures 402 overlying the P well regions to provide for P channel devices, one or more second gate structures 404 overlying the N well region to provide for N channel devices. A third gate structure 406 is formed adjacent to the photosensitive region. The third gate structure can be configured to transfer charges from the photodiode region to, for example, a sensing device (not shown). Each of the gate structures may be formed by depositing and patterning a polysilicon layer in a specific embodiment. The polysilicon layer may be formed using a polysilicon material doped with a suitable impurity, in situ or ex situ, depending on the application. Each of the gate structures may include a silicide layer (not shown) to reduce resistivity in certain embodiment.

The method as shown in FIG. 4 includes forming a blanket spacer dielectric layer 410 overlying each of the gate structures and the exposed gate dielectric layer. The blanket dielectric layer can be a silicon oxide deposited using TEOS (tetraethyloxysilicate) in a plasma environment or commonly known as PE-TEOS (plasma enhanced TEOS). In a specific embodiment, the blanket dielectric layer can be a layer structure such as an oxide on nitride on oxide (ONO) stack. In certain embodiments, the blanket dielectric layer may be silicon nitride or any other suitable dielectric materials or multilayer materials. Of course there can be other modification, variations, and alternatives.

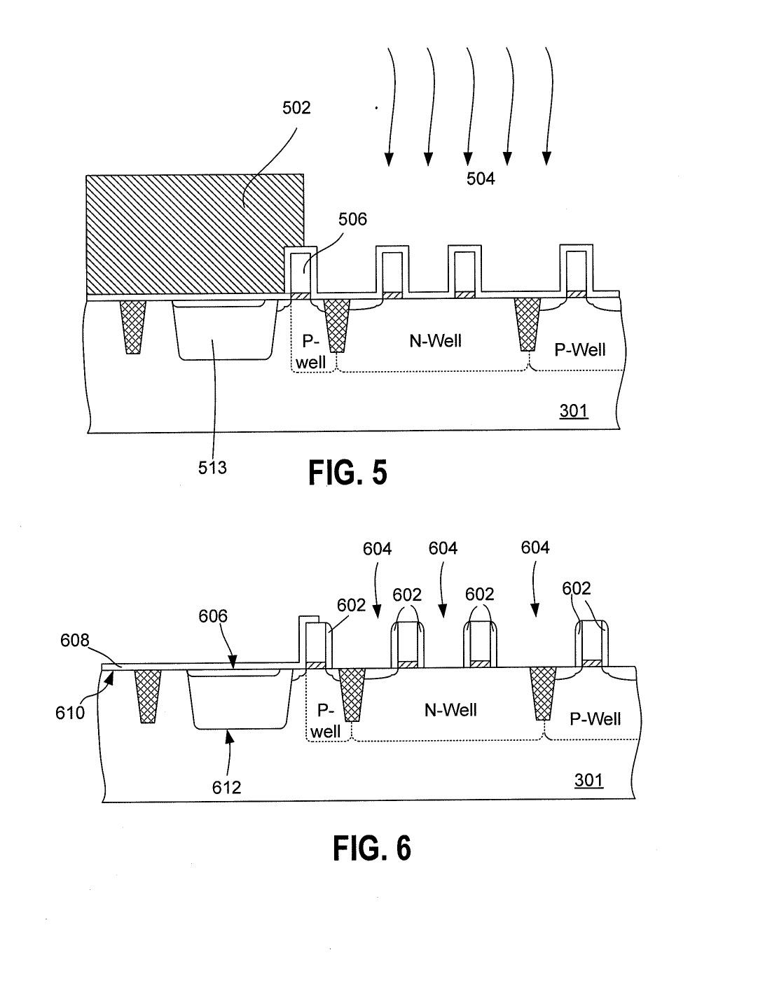

In FIG. 5, the method includes forming a protective layer 502 overlying at least the photodiode device region 513 and a portion of the third gate structure 506 adjacent to the photodiode region while exposing other regions as shown in FIG. 5. In a specific embodiment, the protective layer can be a photoresist material. The protective layer protects the gate dielectric layer overlying the photodiode device region as well as regions surrounding the photodiode device region in a subsequent spacer etch process. Depending upon the embodiment, the protective layer may also be a hard mask such as a suitable dielectric material, or others.

Also shown in FIG. 5, the method includes performing a spacer dielectric etch process 504 on the exposed portion of the blanket dielectric layer while protecting the photodiode device region and a portion of the third gate structure. In a specific embodiment, the spacer dielectric etch process can be provided using an anisotropic dry etch process in a plasma environment. Other etch process such as a wet etch may also be used depending upon the application. Further details are provided below.

As shown in FIG. 6, the spacer dielectric etch process forms dielectric spacer structures 602 overlying the first gate structures for the N channel device, the second gate structures for the P channel device, and the unprotected portion of the third gate structure adjacent to the photodiode device region in a specific embodiment. The dielectric spacer etch process provides dielectric spacer structures overlying the respective gate structures in a single etch step while at least the photo diode device region is being protected by the protective layer. In a specific embodiment, the single etch step prevents misalignment for each of the opening region 604 if each of the opening is to be provided using more than one etch steps. In a specific embodiment, the protective layer prevents defects in photodiode device surface region 606, maintaining integrity of the gate dielectric layer 608 overlying the photodiode device region as well as integrity of gate dielectric/substrate interface region 610. The protective layer also protects an area 612 surrounding the photodiode device region within the substrate, including the surface region. As a result, the leakage current is reduced in a specific embodiment. Of course there can be other variations, modifications, and alternatives.

The method performs other process steps to complete CMOS image sensor device. These other process steps include forming active regions for the photodiode device and source drain regions for the peripheral circuits. The method also forms interlayer dielectric, contact structures, and passivation layer, among others. Of course one skilled in the art would recognize other variations, variations, and alternatives.

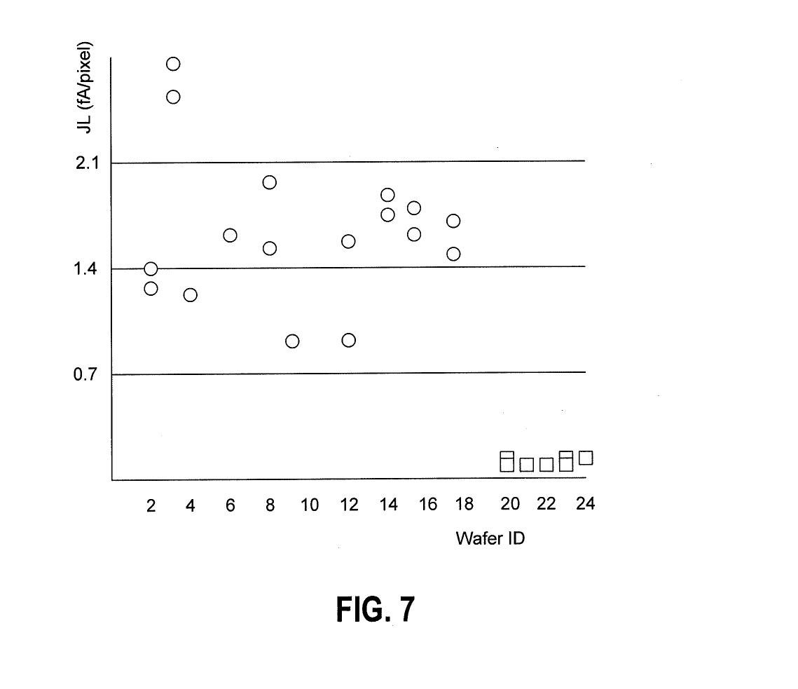

FIG. 7 is a simplified plot 700 of photodiode junction leakage current versus wafer id according to an embodiment of the present invention. As shown, wafers 1-19 were fabricated using conventional method where the gate dielectric layer overlying the photodiode device region was unprotected. Devices in wafers 1-19 showed junction leakage current ranging from about 0.7 fA/pixel to about 2.5 fA/pixel. Wafers 20-24 were fabricated using the present method and devices in wafers 20-24 showed that the junction leakage current is less than about 0.3 fA/pixel. It can be seen that the method provided by embodiments of the invention can be used to reduce the dark leakage current in a CMOS sensor device.

While the above is a description of the specific embodiments, various modifications, alternative constructions and equivalents may be used. For example, the above specification has been described using a P type substrate and a photodiode device region using an N type impurity, an N type substrate and a photodiode device region using P type impurity can also be used. Additionally, the isolation region can be formed using other isolation structures such as a field oxide region among others. Therefore, the above description and illustrations are used only as examples and should not be taken as limiting the scope of the present invention.

What is claimed is:

1. A method of forming a CMOS image sensor device, the method comprising:
providing a semiconductor substrate having a P-type impurity characteristic including a surface region;
forming a gate oxide overlying the surface region;
forming an N-type impurity region in a portion of the semiconductor substrate to form a photodiode device region that includes at least the N-type impurity region;
forming one or more first gate structures overlying a first portion of the gate oxide layer, one or more second gate structure overlying a second portion of the gate oxide layer, and a third gate structure overlying a third portion of the gate oxide layer;
forming a blanket spacer layer overlying the one or more first gate structures, the one or more second gate structures, and the third gate structure;
forming a protective layer overlying the photodiode device region and a first portion of the third gate structure;
forming one or more spacer structures using the blanket spacer layer for the one or more first gate structures, the one or more second gate structures, and a second portion of the third gate structure while maintaining the protective layer overlying the photo diode device region and the first portion of the third gate structure; and
removing the protective layer;
wherein the N-type impurity region is adjacent to the third gate structure.

2. The method of claim 1 further comprising forming P-well regions and N-well regions in the semiconductor substrate.

3. The method of claim 1 wherein the one or more first gate structures are configured to provide for one or more NMOS devices.

4. The method of claim 1 wherein the one or more second gate structures are configured to provide for one or more PMOS devices.

5. The method of claim 1 wherein the third gate structure is formed adjacent to the photodiode device.

6. The method of claim 5 wherein the third gate structure is configured to transfer charges generated in the photodiode device to a sensing device.

7. The method of claim 1 wherein the blanket spacer layer is an ONO stack.

8. The method of claim 1 wherein the forming one or more spacer structures is provided in a single etch process.

9. The method of claim 8 wherein the single etch process is an anisotropic dry etch process in a plasma environment.

10. The method of claim 1 wherein the protective layer is a photoresist material.

11. The method of claim 1 wherein the one or more first gate structures, the one or more second gate structures, and the third gate structures are formed using a doped polysilicon material.

12. The method of claim 1 wherein the photodiode device region further comprises a P type impurity region overlying the N type impurity region to form a pinned type photodiode device.

13. The method of claim 1 wherein the protective layer prevents defects formation in the photodiode device region while forming the one or more spacer structures.

14. The method of claim 1 wherein the protective layer maintains integrity of the gate oxide overlying the photodiode device region and maintains integrity of the gate oxide substrate interface, and maintains integrity of an active region associated with the photodiode device region.

15. The method of claim 1 wherein the CMOS image sensor device has a junction leakage current less than about 0.5 fA/pixel.

16. A method of forming a CMOS image sensor device, the method comprising:
forming a first well region having a first impurity type;
forming a second well region having a second impurity type;
forming a photodiode device region adjacent to the second well region;
forming one or more first gate structures overlying a first portion of the first well region;
forming one or more second gate structures overlying a second portion of the second well region;
forming a third gate structure between the photodiode device region and the second well region;
forming an insulating layer over the first well region, the second well region, the photodiode device region, and the third gate structure;
removing a first portion of the insulating layer over the first well region, a second portion of the insulating layer over the second well region, and a third portion over the third gate structure;
foaming one or more spacers in the first well region, one or more spacers in the second well region, and one spacer adjacent to one side of the third gate structure; and
maintaining a fourth portion of the insulating layer over the photodiode device region and over a portion of the third gate structure adjacent to the photodiode device region.

17. The method of claim 16 further comprising:
after the spacer formation step, using a first mask for implanting impurities of the second type into the first well region.

18. The method of claim 16 further comprising:
after the spacer formation step, using a second mask for implanting impurities of the first type into the second well region.

19. The method of claim 16 wherein the forming one or more spacer structures is provided in a single etch process.

20. The method of claim 16 wherein the CMOS image sensor device has a junction leakage current less than about 0.5 fA/pixel.
